(19) United States
(12) Patent Application Publication
(10) Pub. No.: US 2024/0147712 A1
(43) Pub. Date: May 2, 2024

(54) SEMICONDUCTOR DEVICE AND MANUFACTURING METHOD THEREOF

(71) Applicant: SK hynix Inc., Icheon-si Gyeonggi-do (KR)

(72) Inventor: Jae Young OH, Cheon-si Gyeonggi-do (KR)

(73) Assignee: SK hynix Inc., Icheon-si Gyeonggi-do (KR)

(21) Appl. No.: 18/295,156

(22) Filed: Apr. 3, 2023

(30) Foreign Application Priority Data
Oct. 26, 2022 (KR) 10-2022-0139314

(51) Int. Cl. H10B 41/27; H10B 41/10; H10B 43/10; H10B 43/27

(52) U.S. Cl. CPC H10B 41/27; H10B 41/10; H10B 43/10; H10B 43/27

(57) ABSTRACT

A semiconductor device includes gate structures including conductive layers extending in a first direction; channel structures located in the gate structures and protruding from surfaces of the gate structures; a slit structure located between the gate structures and including a protrusion that protrudes from the surfaces of the gate structures; and a compressive stressor connected to the protrusion of the slit structure and extending in the first direction.

### CROSS-REFERENCE TO RELATED APPLICATION

This application claims priority under 35 U.S.C. § 119(a) to Korean Patent Application No. 10-2022-0139314 filed on Oct. 26, 2022, which is incorporated herein by reference in its entirety.

### BACKGROUND

### 1. Technical Field

Embodiments of the present disclosure relate to an electronic device, and more particularly, to a semiconductor device and a manufacturing method thereof.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include gate structures including conductive layers extending in a first direction; channel structures located in the gate structures and protruding from surfaces of the gate structures; a slit structure located between the gate structures and including a protrusion that protrudes from the surfaces of the gate structures; and a compressive stressor connected to the protrusion of the slit structure and extending in the first direction.

In an embodiment, a semiconductor device may include a source structure located on a substrate; gate structures located on the substrate, including gate lines extending in a first direction, and located to be adjacent to each other in a second direction that is perpendicular to the first direction; a slit structure located between the gate structures and protruding into the source structure along a third direction that is perpendicular to both the first direction and the second direction; and an oxidized pattern located inside the source structure to extend in the first direction, extending in the first direction inside the source structure, and pressing the substrate in the third direction.

In an embodiment, a manufacturing method of a semiconductor device may include forming, on a base, a stack including first material layers and second material layers that are alternately stacked; forming a channel structure that passes through the stack and extending into the base; forming a slit that passes through the stack and extending into the base; forming an impurity region on a bottom surface of the slit; forming a compressive stressor inside the base by oxidizing the impurity region; and forming, in the slit, a slit structure connected to the compressive stressor and the base.

### BRIEF DESCRIPTION OF THE DRAWINGS

FIG. 1A to FIG. 1C are diagrams for describing the structure of a semiconductor device in accordance with an embodiment.

FIG. 2A and FIG. 2B are diagrams for describing the structure of a semiconductor device in accordance with an embodiment.

FIG. 3A to FIG. 3C are diagrams for describing warpage of a semiconductor device in accordance with an embodiment.

FIG. 4A to FIG. 4D are diagrams for describing a manufacturing method of a semiconductor device in accordance with an embodiment.

FIG. 5A to FIG. 5F are diagrams for describing a manufacturing method of a semiconductor device in accordance with an embodiment.

### DETAILED DESCRIPTION

Various embodiments are directed to a semiconductor device having a stable structure and improved characteristics and a manufacturing method thereof.

By stacking memory cells in three dimensions, it is possible to improve the degree of integration of a semiconductor device. Furthermore, it is possible to provide a semiconductor device having a stable structure and improved reliability.

Hereafter, embodiments in accordance with the technical spirit of the present disclosure will be described with reference to the accompanying drawings.

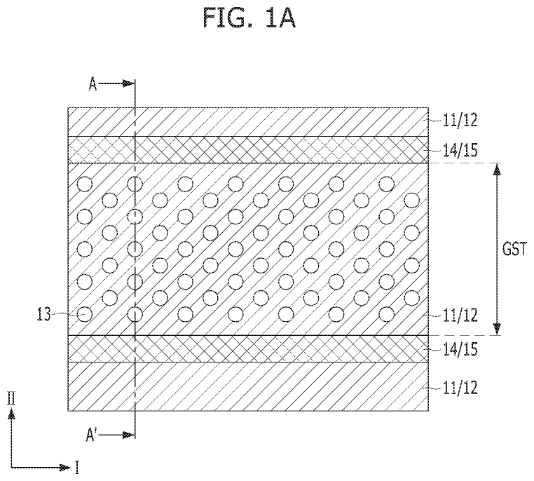

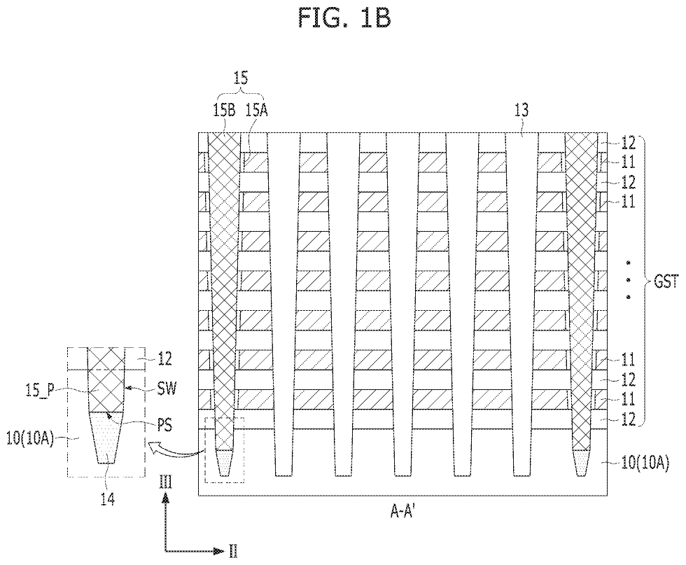

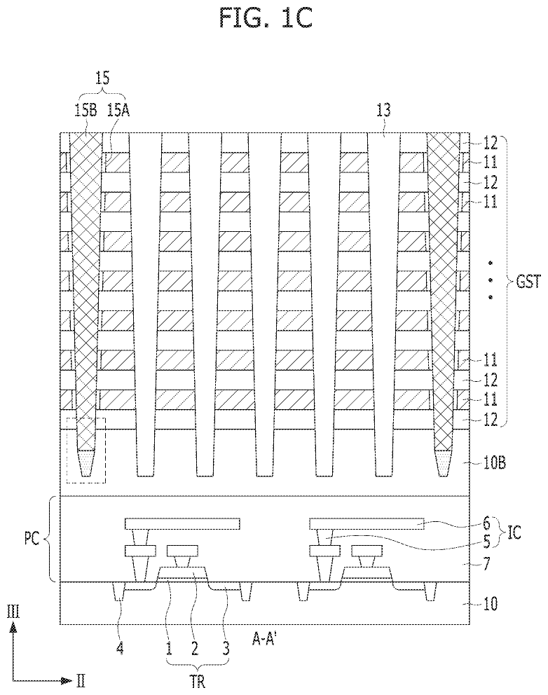

FIG. 1A to FIG. 1C are diagrams for describing the structure of a semiconductor device in accordance with an embodiment. FIG. 1A may be a plan view, and FIG. 1B or FIG. 1C may be a cross-sectional view taken along line A-A′ in FIG. 1A.

Referring to FIG. 1 and FIG. 1B, the semiconductor device may include a substrate 10, a plurality of gate structures GST, channel structures 13, a compressive stressor 14, or a slit structure 15, or a combination thereof. The substrate 10 may include a well region 10A. The well region 10A may be a p-type well that is formed by implanting p-type impurities, such as boron (B).

The plurality of gate structures GST may be located on the substrate 10. The gate structure GST may include stacked conductive layers 11. In a plane that is defined by a first direction I and a second direction II crossing the first direction I, the conductive layers 11 may extend in the first direction I. As an example, the second direction II may substantially be perpendicular to the first direction I. The gate structures GST may be adjacent to each other in the second direction II.

As an example, each of the gate structures GST may include the conductive layers 11 and insulating layers 12 that are alternately stacked. The conductive layers 11 may be gate lines, such as word lines, bit lines, and select lines. The conductive layers 11 may each include a conductive material, such as polysilicon or metal. The conductive layers 11 may each include a tensile stress material. As an example, the conductive layers 11 may each include a metal, such as tungsten (W) or molybdenum (Mo) and may be contracted to apply tensile stress to peripheral layers in the process of forming a metal layer.

The slit structure 15 may be located between the gate structures GST. The slit structure 15 may extend in the first direction I. The slit structure 15 may have substantially the same height as or a different height from the gate structures GST. The slit structure 15 may include a protrusion 15_P that protrudes from surfaces of the gate structures GST. As an example, an upper surface of the slit structure may be located on substantially the same plane as upper surfaces of the gate structures GST, and the protrusions 15_P may protrude from the plane of the lower surfaces of the gate structures GST. The protrusions 15_P may be located inside of the substrate 10. As an example, the protrusion 15_P may be located inside of the well region 10A. The protrusion 15_P may include a protruding surface PS and a sidewall SW.

The slit structure 15 may include an insulating material, such as oxide, nitride, or air gap, a conductive material, such as polysilicon, tungsten, or molybdenum, or a combination thereof. The slit structure 15 may include a tensile stress material or a compressive stress material. The slit structure 15 may be contracted or expanded during the formation process thereof to apply tensile stress or compressive stress to peripheral layers.

The slit structure 15 may include a source contact plug 15B and an insulating spacer 15A that surrounds a sidewall of the source contact plug 15B. The source contact plug 15B may be electrically connected to a source region or a source structure. The insulation spacers 15A may be located between the source contact plug 15B and the conductive layers 11. Alternatively, the insulating spacer 15A may be located between the source contact plug 15B and the gate structure GST. The source contact plug 15B may include a conductive material, such as polysilicon, tungsten, or molybdenum.

The compressive stressor 14 may reduce wafer warpage by applying compressive stress to a wafer. The compressive stressor 14 may be connected to the protrusion 15_P of the slit structure 15. The compressive stressor 14 may selectively cover the protruding surface PS, among the protruding surface PS and the sidewall SW of the protrusion 15_P. The compressive stressor 14 might not cover the sidewall SW of the protrusion 15_P. The compressive stressor 14 may directly contact the protruding surface PS. The compressive stressor 14 may extend in the first direction I. In the plane, the compressive stressor 14 may be located between the gate structures GST that is adjacent in the second direction II. The compressive stressor 14 may be located inside of the substrate 10. The compressive stressor 14 may be located inside of the well region 10A.

The compressive stressor 14 may include a material that causes compressive stress. The compressive stressor 14 may include an insulating material, such as oxide or nitride. The compressive stressor 14 may be an insulating stressor. As an example, the compressive stressor 14 may include oxide that is formed by selectively oxidizing an impurity region in the substrate 10. The compressive stressor 14 may be an oxidized pattern, the volume of which is expanded by the oxidizing process. The compressive stressor 14 may include a dopant. As an example, the compressive stressor 14 may include boron (B), phosphorus (P), or arsenic (As), or a combination thereof.

The channel structures 13 may be located in the gate structures GST. Referring to FIG. 1B, in a cross section that is defined by the second direction II and the third direction III, the channel structures 13 may extend in the third direction III. Furthermore, the third direction III may be a direction that protrudes from a plane that is defined by the first direction I and the second direction II. The channel structures 13 may have substantially the same height as or a different height from the gate structures GST. The channel structures 13 may protrude from the surfaces of the gate structures GST. As an example, the channel structures 13 may protrude from the lower surfaces of the gate structures GST and may extend into the substrate 10. The channel structures 13 may be directly connected to the substrate 10 or may be connected to the substrate 10 through an epitaxial pattern or the like.

The channel structures 13 may include a channel layer and a memory layer that surrounds a sidewall of the channel layer. The memory layer may include a tunneling layer, a data storage layer, or a blocking layer, or a combination thereof. The data storage layer may include a floating gate, polysilicon, a charge trap material, nitride, or a variable resistance material, or a combination thereof. For reference, the semiconductor device may also include an electrode structure instead of the channel structure 13. The electrode structure may include an electrode layer and a variable resistance layer that surrounds an outer wall or an inner wall of the electrode layer.

Referring to FIGS. 1A and 1C, the semiconductor device may further include a source structure 10B. The source structure 10B may be located between the substrate 10 and the gate structures GST. The source structure 10B may include a conductive material, such as polysilicon or metal. The source structure 10B may be a single layer or a multilayer layer. The slit structure 15 and the channel structure 13 may extend into the source structure 10B. The compressive stressor 14 may be located inside of the source structure 10B.

The semiconductor device may further include a peripheral circuit PC that is located on the substrate 10. The peripheral circuit PC may include circuits, such as a page buffer and a decoder. As an example, the peripheral circuit PC may include an isolation layer 4 in the substrate 10 and a transistor TR that is located in an active region that is defined by the isolation layer 4. The transistor TR may include a gate insulating layer 1, a gate electrode 2, and a junction 3. The semiconductor device may further include an interconnection structure IC that is electrically connected to the peripheral circuit PC. The interconnection structure IC may include a contact plus 5 and a wiring line 6. The interconnection structure IC may be located in an interlayer dielectric layer 7. The peripheral circuit PC and the gate structure GST may be sequentially formed on substantially the same wafer or may be manufactured on separate wafers and then bonded.

According to the structure described above, tensile stress may be caused by the conductive layers 21 that extend in the first direction I, and the substrate 10 may be pulled and warped in the third direction III by the tensile stress. Furthermore, compressive stress may be caused by the compressive stressor 14 that extends in the first direction I, and the substrate 10 may be pressed in the third direction III by the compressive stress. Therefore, tensile stress may be offset by compressive stress, and wafer warpage of the semiconductor device may be reduced.

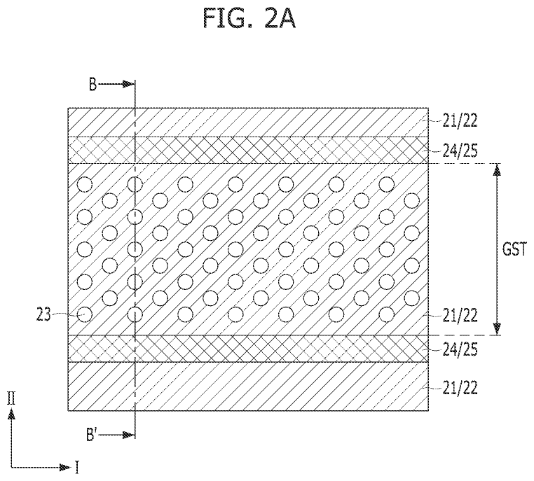

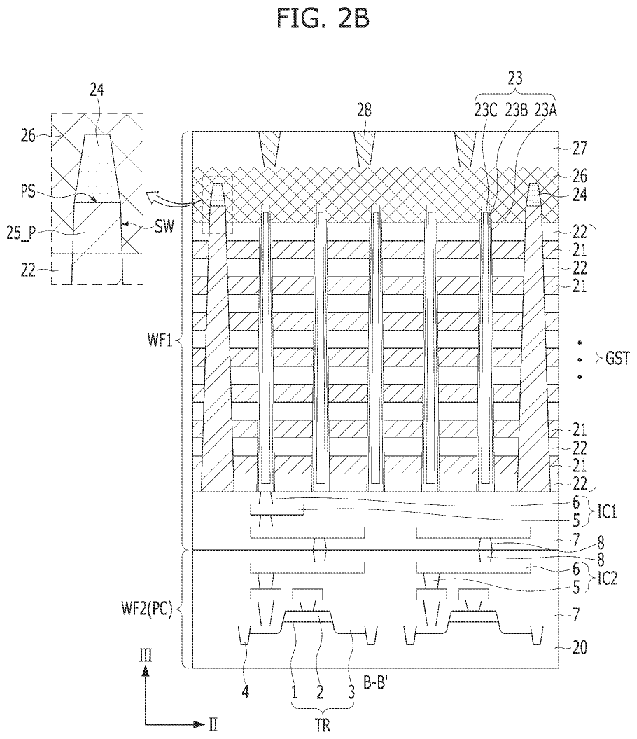

FIG. 2A and FIG. 2B are diagrams for describing the structure of a semiconductor device in accordance with an embodiment. FIG. 2A may be a plan view, and FIG. 2B may be a cross-sectional view taken along line B-B′ in FIG. 2A. Hereinafter, the content overlapping with the previously described content will be omitted.

Referring to FIG. 2A and FIG. 2B, the semiconductor device may include a first wafer WF1 and a second wafer WF2 and may have a structure in which the first wafer WF1 and the second wafer WF2 are bonded to each other. The first wafer WF1 may include a cell array and stacked memory cells. The second wafer WF2 may include a peripheral circuit PC for driving the cell array. The peripheral circuit PC may include an isolation layer 4 in a substrate 20 and a transistor TR that is located in an active region that is defined by the isolation layer 4. The transistor TR may include a gate insulating layer 1, a gate electrode 2, and a junction 3. The semiconductor device may further include a second interconnection structure IC2 that is electrically connected to the peripheral circuit PC. The second interconnection structure IC2 may include a contact plus 5 and an interconnection 6. The semiconductor device may further include a bonding pad 8 for bonding the first wafer WF1 and the second wafer WF2.

For reference, the second wafer WF2 may also include a cell array or an interconnection structure. The semiconductor device may have a structure in which a plurality of wafers are bonded to each other.

The first wafer WF1 may include gate structures GST, channel structures 23, a compressive stressor 24, a slit structure 25, a source structure 26, an interlayer dielectric layer 27, and an interconnection structure 28, an interlayer dielectric layer 7, a first interconnection structure IC1, or the bonding pad 8, or a combination thereof.

Each of the gate structures GST may include conductive layers 21 that extend in the first direction I. The gate structure GST may include the conductive layers 21 and insulating layers 22 that are alternately stacked. The source structure 26 may be located on the gate structures GST. The source structure 26 may include a conductive material, such as polysilicon, tungsten, or molybdenum. The channel structures 23 may be located in the gate structures GST and may protrude from surfaces of the gate structures GST. As an example, the channel structures 23 may protrude from upper surfaces of the gate structures GST and may extend into the source structure 26. The interconnection structure 28 may be located on the source structure 26 and may be located in the interlayer dielectric layer 27.

The slit structure 25 may be located between the gate structures GST. The slit structure 25 may include protrusions 25_P that protrude from the surfaces of the gate structures GST. As an example, the protrusions 25_P may protrude from upper surfaces of the gate structures GST. The protrusions 25_P may be located inside of the source structure 26. The protrusion 25_P may include a protruding surface PS and a sidewall SW.

The slit structure 25 may include an insulating material, such as oxide, nitride, or air gap, or a conductive material, such as polysilicon, tungsten, or molybdenum, or a combination thereof. As an example, the slit structure 25 may include a compressive stress material and may be an insulating layer.

The compressive stressor 24 may be connected to the protrusion 25_P of the slit structure 25. The compressive stressor 24 may selectively cover the protruding surface PS among the protruding surface PS and the sidewall SW of the protrusion 25_P. The compressive stressor 24 might not cover the sidewall SW of the protrusion 25_P. The compressive stressor 24 may directly contact the protruding surface PS. The compressive stressor 24 may extend in the first direction I. The compressive stressor 24 may be located inside the source structure 26.

The compressive stressor 24 may include a compressive stress material. The compressive stress may be applied to a wafer by the compressive stressor 24. The compressive stressor 24 may include an insulating material, such as oxide or nitride. As an example, the compressive stressor 24 may include an oxide that is formed by selectively oxidizing an impurity region. The compressive stressor 24 may include a dopant. As an example, the compressive stressor 24 may include boron (B), phosphorus (P), or arsenic (As), or may include a combination thereof.

Each of the channel structures 33 may include a channel layer 23B. Each of the channel structures 33 may further include a memory layer 23A that surrounds a sidewall of the channel layer 23B or an insulating core 23C within the channel layer 23B, or a combination thereof. The memory layer 23A may include a tunneling layer, a data storage layer, or a blocking layer, or a combination thereof. The data storage layer may include a floating gate, polysilicon, a charge trap material, a nitride, or a variable resistance material, or a combination thereof.

According to the structure described above, compressive stress may be applied to the wafer by the compressive stressor 24. Therefore, tensile stress that is caused by the conductive layers 21 or the like may be offset by the compressive stress that is applied by the compressive stressor 24. When the slit structure 25 includes an insulating layer, compressive stress may be applied to the wafer by the slit structure 25 and the compressive stressor 24. Accordingly, compressive stress having sufficient magnitude may be applied to the wafer, and the magnitude of the compressive stress may be finely adjusted through the compressive stressor 24.

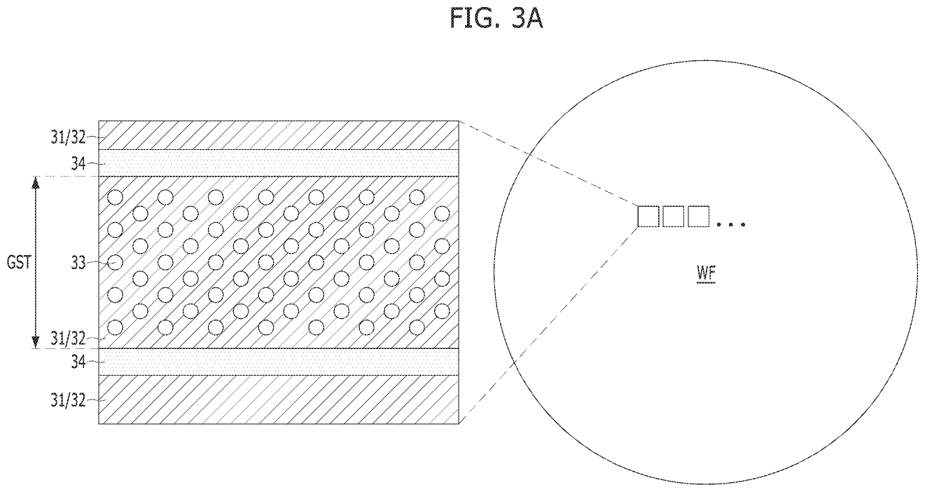

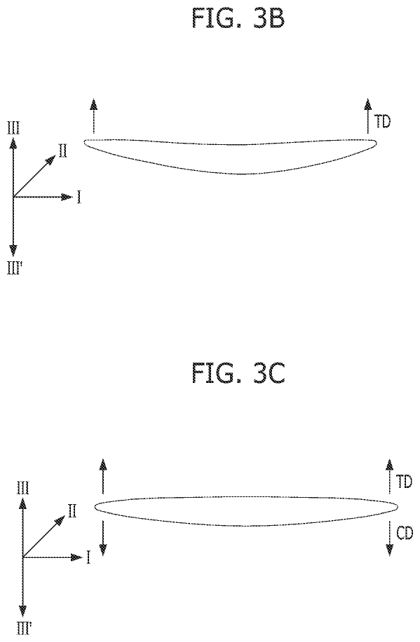

FIG. 3A to FIG. 3C are diagrams for describing warpage of a semiconductor device in accordance with an embodiment. Hereinafter, the content overlapping with the previously described content will be omitted.

Referring to FIG. 3A, a wafer WF may include gate structures GST, a channel structure 33, or a compressive stressor 34, or a combination thereof. The wafer WF may extend along a plane that is defined by the first direction I and a second direction II. The gate structure GST may include conductive layers 31 and insulating layers 32 that are alternately stacked. The compressive stressor 34 may be located between the gate structures GST and may be located inside of a source structure or a substrate.

Referring to FIGS. 3A and 3B, the conductive layers 31 may extend in the first direction I. In the process of forming the conductive layers 31, tensile stress may be applied to the wafer WF due to deformation, such as contraction. The wafer WF may be warped in a tensile direction TD by the tensile stress. In such a case, the tensile direction TD to which the tensile stress is applied may vary according to the shape of the conductive layers 31, and the shape in which the wafer WF is warped may vary. As an example, the wafer WF may be pulled and warped in a third direction III by the conductive layers 31.

Referring to FIGS. 3A and 3C, the compressive stressor 34 may extend in the first direction I. In the process of forming the compressive stressor 34, compressive stress may be applied to the wafer WF due to deformation, such as expansion. Due to the compressive stress, the wafer WF may be pressed in a compression direction CD. In such a case, the compression direction CD in which the compressive stress is applied may vary according to the shape of the compressive stressor 34, and the shape in which the wafer WF is pressed may vary. As an example, the compressive stressor 34 may press the wafer WF in a third direction III′, which is the opposing direction of the third direction III of the tensile direction TD.

According to the structure described above, since both the conductive layers 31 and the compressive stressor 34 extend along the first direction I, tensile stress and compressive stress may be applied to the wafer WF along the third direction III-III′ in opposing directions. Accordingly, stresses of the same type may be applied to the wafer WF in opposing directions, which makes it possible to reduce warpage of the wafer WF.

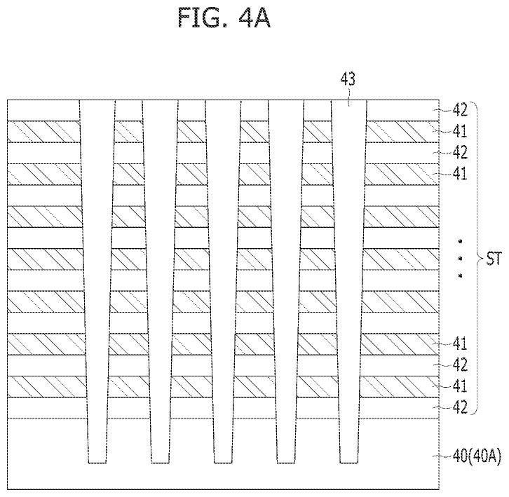

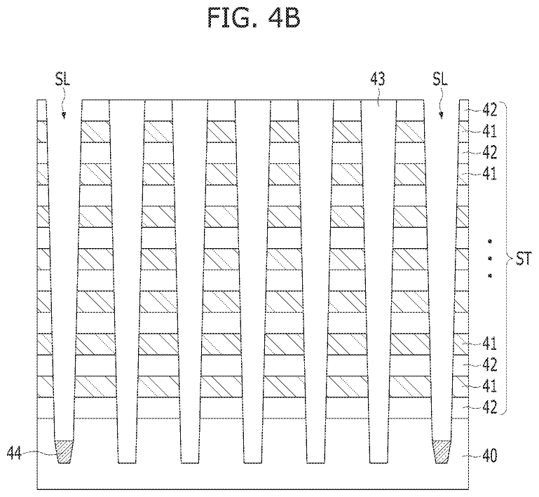

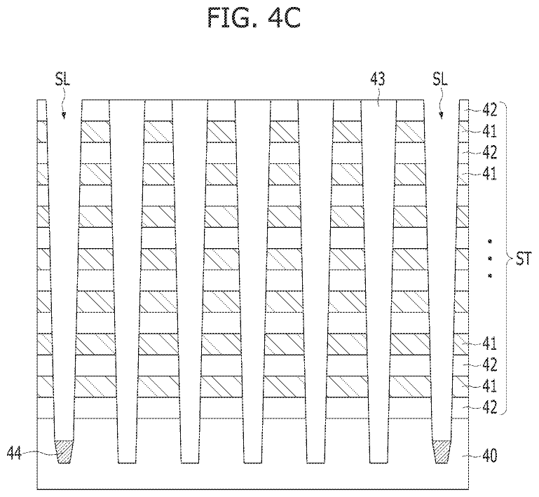

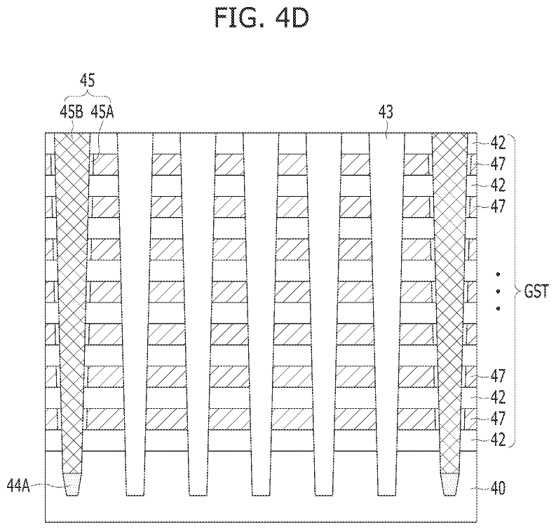

FIG. 4A to FIG. 4D are diagrams for describing a manufacturing method of a semiconductor device in accordance with an embodiment. Hereinafter, the content overlapping with the previously described content will be omitted.

Referring to FIG. 4A, a stack ST may be formed on a base 40. The base 40 may include a substrate, a peripheral circuit, a source structure, or the like, or a combination thereof. As an example, the base 40 may be a substrate, and after a well region 40A is formed in the substrate, the stack ST may be formed on the substrate. As an example, the base 40 may be a source structure, and the stack ST may be formed on the source structure. The source structure may include a conductive material or a source sacrificial layer.

The stack ST may include first material layers 41 and second material layers 42 that are alternately stacked. The first material layers 41 may be used to form gate lines, such as word lines, bit lines, and select lines. The second material layers 42 may insulate stacked gate lines from each other. The first material layers 41 may each include a material having a high etch selectivity with respect to the second material layers 42. For example, the first material layers 41 may each include a sacrificial layer, such as nitride, and the second material layers 42 may each include an insulating layer, such as oxide. As another example, the first material layers 41 may each include a conductive material, such as polysilicon or metal, and the second material layers 42 may each include an insulating layer, such as an oxide.

Subsequently, a channel structure 43 may be formed in the stack ST. The channel structure 43 may pass through the stack ST and extend into the base 40. As an example, the channel structure 43 may include a channel layer and a memory layer that surrounds a sidewall of the channel layer. The memory layer may include a tunneling layer, a data storage layer, or a blocking layer, or a combination thereof. The data storage layer may include a floating gate, polysilicon, a charge trap material, nitride, or a variable resistance material, or a combination thereof. For reference, an electrode structure may also be formed instead of the channel structure 43. The electrode structure may include an electrode layer and a variable resistance layer that surrounds an outer wall or an inner wall of the electrode layer.

Referring to FIG. 4B, slits SL may be formed in the stack ST. The slits SL may pass through the stack ST and may extend into the base 40. A bottom surface BS of the slit SL may be located below a surface SF of the base 40. The base 40 may be exposed through the bottom surface BS and an inner wall IW of the slit SL.

Subsequently, an impurity region 44 may be formed in the base 40. The impurity region 44 may be formed in the base 40 that is exposed through the bottom surface BS of the slit SL. The impurity region 44 may be selectively formed in a portion of the base 40 that is exposed through the bottom surface BS of the slit SL. The impurity region 44 might not be formed in a portion of the base 40 that is exposed through the inner wall IW of the slit SL.

The impurity region 44 may be formed through the slit SL. The impurity region 44 may be formed by doping the surface of the base 40 that is exposed through the slit SL with an impurity. The impurity may include boron (B), phosphorus (P), or arsenic (As), or a combination thereof.

The position of the impurity region 44 may be adjusted according to an impurity doping method. The impurity region 44 may be formed by ion implantation. The impurity region 44 may be formed by implanting impurities into the bottom surface of the slit SL. The bottom surface BS of the slit BS may be doped with impurities by using the directionality of ion implantation, and no impurities may be doped or the inner wall IW may be doped with less impurities compared to the bottom surface BS. Accordingly, the impurity region 44 may be formed at a predetermined depth along the bottom surface BS of the slit SL. The impurity region 44 may be spaced apart from the surface SF of the base 40. Between the impurity region 44 and the stack ST, the base that is not substantially doped with impurities or having a low impurity concentration may be exposed.

Referring to FIG. 4C, a compressive stressor 44A may be formed in the base 40. The compressive stressor 44A may be located on the bottom surface of the slit SL and may be spaced apart from the surface of the base 40. The compressive stressor 44A may include a compressive stress material. The compressive stressor 44A may include an insulating material, such as oxide or nitride.

As an example, the compressive stressor 44A may be formed by selectively oxidizing the impurity region 44. The oxidation process may be performed through a dry or wet thermal oxidation (DRY/WET thermal oxidation) method. The compressive stressor 44A may be a polysilicon layer that is doped with impurities or a silicon oxide layer formed by oxidizing a silicon substrate that is doped with impurities.

During the oxidation process, a region that is doped with impurities may be more oxidized than a region not substantially doped with impurities or having a low impurity doping concentration. A growth rate of an oxide layer in the impurity region 44 of the base 40 may be higher than those of the other regions. Accordingly, the compressive stressor 44A may be formed on the bottom surface of the slit SL, and the compressive stressor 44A might not be formed on the inner wall IW of the slit SL, or the formation of the compressive stressor 44A may be reduced.

When the compressive stressor 44A is formed without the impurity region 44, the surface of the base 40 that is exposed through the bottom surface BS and the inner wall IW of the slit SL may be oxidized. In such a case, the compressive stressor 44A may be formed on the inner wall IW as well as the bottom surface BS of the slit SL and may cause an abnormal profile, such as a bird's beak shape. Accordingly, the location where the compressive stressor 44A is to be formed through the impurity region 44 may be limited, which makes it possible to prevent or reduce the occurrence of an abnormal profile.

When the compressive stressor 44A is formed, the volume of the compressive stressor 44A may expand while the impurity region 44 is being oxidized. The volume-expanded compressive stressor 44A may apply compressive stress to a wafer. Therefore, tensile stress to the wafer, which has been caused in the previous process or which is caused in a subsequent process, may be offset.

Referring to FIG. 4D, third material layers 47 may be formed. After the first material layers 41 are removed through the slit SL, the third material layers 47 may be formed. Alternatively, the third material layers 47 may be formed by performing a process for lowering the resistance of the first material layers 41, such as a silicidation process. Accordingly, the first material layers 41 may be replaced with the third material layers 47. As a result, a gate structure GST including the second material layers 42 and the third material layers 47 that are alternately stacked may be formed.

When the compressive stressor 44A has an abnormal profile such as a bird's beak, the profile of the lowermost first material layer 41 may be deformed. In such a case, in the process of replacing the first material layers 41 with the third material layers 47, the lowermost first material layer 41 might not be sufficiently removed and the lowermost gate line might not be properly formed. Therefore, the compressive stressor 44A may be formed only on the bottom surface BS of the slit SL, which makes it possible to prevent or reduce gate line formation failure.

When the third material layers 47 include metal, such as tungsten or molybdenum, the third material layers 47 may be contracted during the formation process thereof. The contraction may cause tensile stress and may apply the tensile stress to the wafer. The tensile stress may be offset by compressive stress from the compressive stressor 44A.

Although not illustrating in the drawing, an additional process for forming a source layer may be performed before or after the first material layers 41 are replaced with the third material layers 47. As an example, when the source structure includes a source sacrificial layer, the source layer that is connected to the channel structure 43 may be formed after the source sacrificial layer in the source structure is removed through the slit SL.

Subsequently, a slit structure 45 that is connected to the compressive stressor 44A may be formed in the slit SL. The slit structure 45 may include an insulating material, such as oxide, nitride, or air gap, or a conductive material, such as polysilicon, tungsten, or molybdenum, or a combination thereof. As an example, an insulating spacer 45A may be formed, and a source contact plug 45B may be formed in the insulating spacer 45A. The insulating spacers 45A may be located between the source contact plug 45B and the third material layers 47 or may be located between the source contact plug 45B and the gate structure ST.

The base 40 may be exposed between the compressive stressor 44A and the gate structure GST, and the source contact plug 45B may be connected to the exposed base 40. The source contact plug 45B may include a conductive material and may be electrically connected to the base 40.

According to the manufacturing method as described above, warpage of a wafer may be reduced by forming the compressive stressor 44A on the bottom surface of the slit SL. Furthermore, by forming the compressive stressor 44A by oxidizing the impurity region 44, the compressive stressor 44A may be formed only on the bottom surface of the slit SL, which makes it possible to reduce the occurrence of an abnormal profile in the manufacturing process.

The material, size, shape, and the like of the compressive stressor 44A may be determined in consideration of the warpage of a wafer. As an example, after a test wafer including no compressive stressor 44A is produced, warpage of the test wafer may be measured. Based on the measured warpage, the magnitude of compressive stress to offset tensile stress may be calculated, and the compressive stressor 44A may be designed to cause compressive stress having the corresponding magnitude. The wafer warpage may be reduced by adjusting the size of an impurity region, the type of impurity to be doped, the doping concentration of the impurity, the condition of an oxidation process, the size of compressive stressor, and the like based on the measured warpage.

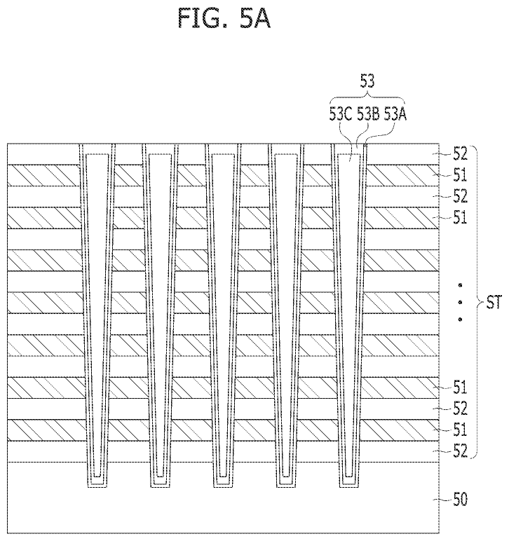

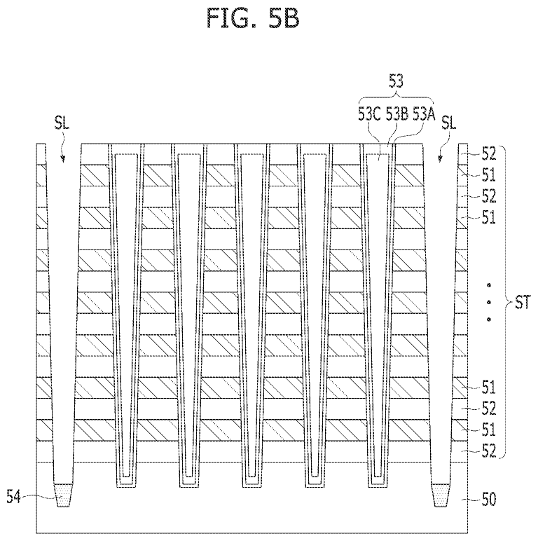

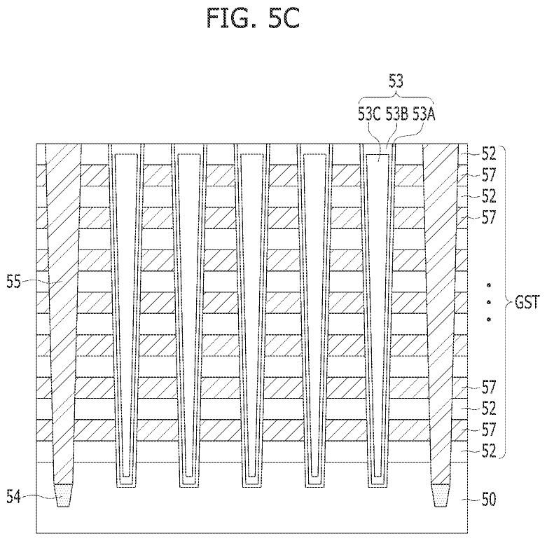

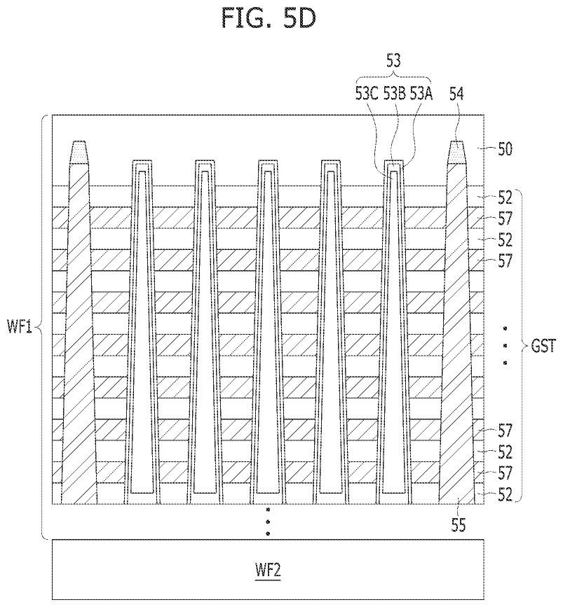

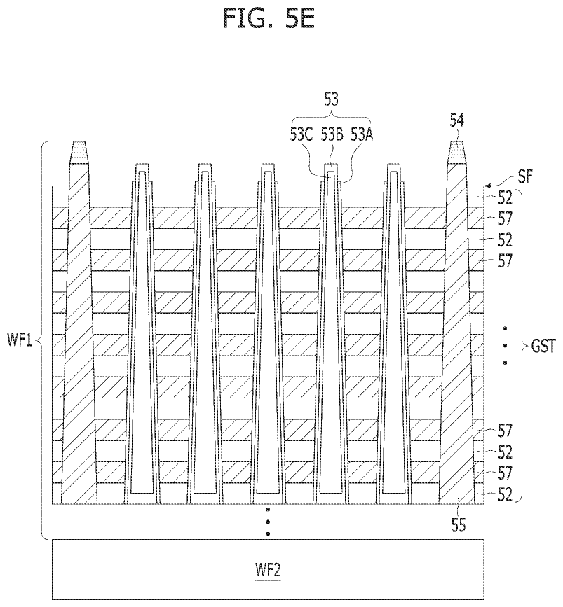

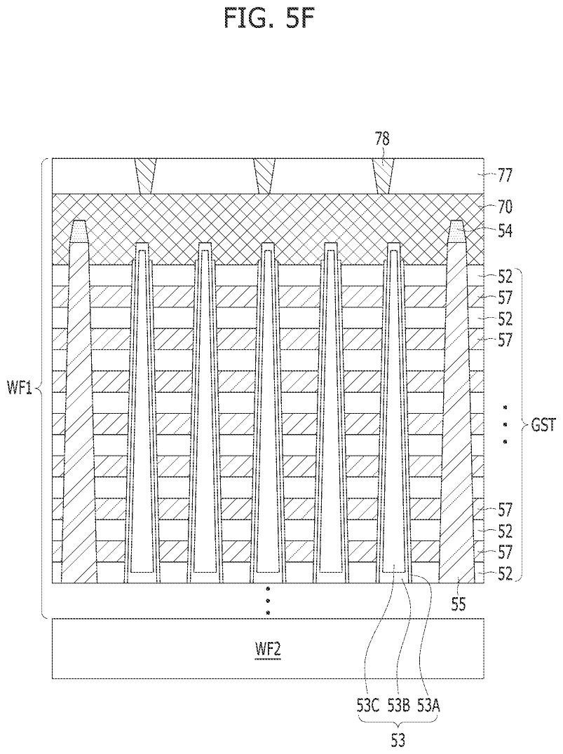

FIG. 5A to FIG. 5F are diagrams for describing a manufacturing method of a semiconductor device in accordance with an embodiment. Hereinafter, the content overlapping with the previously described content will be omitted.

Referring to FIG. 5A, a stack ST may be formed on a base 50. As an example, the base 50 may include a silicon substrate. The stack ST may include first material layers 51 and second material layers 52 that are alternately stacked.

Subsequently, a channel structure 53 may be formed in the stack ST. As an example, an opening may be formed in the stack ST, and a memory layer 53A, a channel layer 53B, and an insulating core 53C may be formed in the opening. For reference, an electrode structure may also be formed instead of the channel structure 53.

Referring to FIG. 5B, slits SL may be formed in the stack ST. The slits SL may pass through the stack ST and may extend into the base 50. Subsequently, a compressive stressor 54 may be formed inside of the base 50. The compressive stressor 54 may be formed by selectively oxidizing a portion of the base 50 that is exposed through a bottom surface of the slit SL. As an example, after an impurity region in the base 50 is formed, the compressive stressor 54 may be formed by selectively oxidizing the impurity region. The volume of the compressive stressor 54 may expand while the impurity region is being oxidized, which may cause compressive stress.

Referring to FIG. 5C, the first material layers 51 may be replaced with third material layers 57 through the slit SL. Accordingly, a gate structure GST including the second material layers 52 and the third material layers 57 that are alternately stacked may be formed. Subsequently, a slit structure 55 that is connected to the compressive stressor 54 may be formed in the slit SL. The slit structure 55 may include an insulating material, such as oxide, nitride, or air gap, a conductive material, such as polysilicon, tungsten, or molybdenum, or a combination thereof. As an example, the slit structure 55 may include an insulating layer.

Subsequently, although not illustrated in the drawing, an additional process, such as forming an interconnection structure that is connected to the channel structure 53 may be performed.

Referring to FIG. 5D, a first wafer WF1 including the base 50, the gate structure GST, the channel structure 53, the compressive stressor 54, and the slit structure 55, may be bonded to a second wafer WF2 including a peripheral circuit. Subsequently, the first wafer WF1 that is bonded to the second wafer WF1 may be inverted so that the base 50 is located on an upper portion.

Referring to FIG. 5E, the base 50 may be removed. Accordingly, the channel structure 53, the compressive stressor 54, and the slit structure 55 may be exposed. A part of the channel structure 53 may protrude from a surface SF of the gate structure GST, and the memory layer 53A corresponding to the protruding portion may be exposed. A part of the slit structure 55 may protrude from the surface SF of the gate structure GST. The compressive stressor 54 may be connected to the protruding portion of the slit structure 55 and may be spaced apart from the surface SF.

Subsequently, the memory layer 53A may be partially removed. An exposed portion of the memory layer 53A protruding from the surface SF may be removed. The memory layer 53A may be selectively etched to expose the channel layer 53B. When the memory layer 53A is etched, the compressive stressor 54 or the slit structure 55 may be partially etched.

Referring to FIG. 5F, a source structure 70 may be formed. The source structure 70 may include a conductive material, such as polysilicon or metal. The source structure 70 may be formed on the surface SF of the gate structure GST and may be formed to surround the channel structure 53 that protrudes from the surface SF, the slit structure 55, and the compressive stressor 54. The compressive stressor 54 may be located inside of the source structure 70.

Subsequently, an interconnection structure 78 and an interlayer dielectric layer 77 may be formed on the source structure 70. The interconnection structure 78 may be located in the interlayer dielectric layer 77 and may be electrically connected to the channel structure 53, the third material layer 57, and the like.

According to the manufacturing method as described above, the compressive stressor 54 may be formed on the bottom surface of the slit SL, which makes it possible to reduce warpage of a wafer. Furthermore, by forming the compressive stressor 54 by oxidizing an impurity region, the compressive stressor 54A may be formed only on the bottom surface of the slit SL, which makes it possible to reduce the occurrence of failure in the manufacturing process.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
gate structures comprising conductive layers extending in a first direction;
channel structures located in the gate structures and protruding from surfaces of the gate structures;
a slit structure located between the gate structures and comprising a protrusion that protrudes from the surfaces of the gate structures; and
a compressive stressor connected to the protrusion of the slit structure and extending in the first direction.

2. The semiconductor device of claim 1, wherein the compressive stressor comprises an insulating material.

3. The semiconductor device of claim 1, wherein the protrusion of the slit structure comprises a protruding surface and a sidewall, and
wherein the compressive stressor selectively surrounds the protruding surface.

4. The semiconductor device of claim 1, wherein the compressive stressor comprises a dopant.

5. The semiconductor device of claim 1, wherein the compressive stressor comprises boron (B), phosphorus (P), or arsenic (As), or a combination thereof.

6. The semiconductor device of claim 1, wherein the gate structures are adjacent to each other in a second direction that is perpendicular to the first direction.

7. The semiconductor device of claim 1, further comprising:
a substrate comprising a well region,
wherein the protrusion of the slit structure and the compressive stressor are located inside the well region.

8. The semiconductor device of claim 1, wherein the slit structure comprises:
a source contact plug; and
an insulating spacer surrounding a sidewall of the source contact plug.

9. The semiconductor device of claim 1, further comprising:
a source structure,
wherein the protrusion of the slit structure and the compressive stressor are located inside the source structure.

10. The semiconductor device of claim 1, wherein the slit structure comprises an insulating layer.

11. A semiconductor device comprising:
a source structure located on a substrate;
gate structures located on the substrate, comprising gate lines extending in a first direction, and located to be adjacent to each other in a second direction crossing the first direction;
a slit structure located between the gate structures and protruding into the source structure along a third direction crossing the first direction and the second direction; and
an oxidized pattern extending in the first direction inside the source structure and pressing the substrate in the third direction.

12. The semiconductor device of claim 11, wherein the oxidized pattern is connected to the slit structure.

13. The semiconductor device of claim 11, wherein the oxidized pattern comprises a dopant.

14. The semiconductor device of claim 11, wherein the oxidized pattern comprises boron (B), phosphorus (P), or arsenic (As), or a combination thereof.
